(19) United States
(12) Patent Application Publication
(10) Pub. No.: US 2025/0113654 A1
(43) Pub. Date: Apr. 3, 2025

(54) SOLAR MODULE

(71) Applicant: Markus Gisler, Niederbipp (CH)

(72) Inventor: Markus Gisler, Niederbipp (CH)

(21) Appl. No.: 18/725,534

(22) PCT Filed: Dec. 21, 2022
(86) PCT No.: PCT/EP2022/087344

§ 371 Date: Jun. 28, 2024

(30) Foreign Application Priority Data
Jan. 4, 2022 (CH) CH000016/2022

(51) Int. Cl. H10F 77/42

(52) U.S. Cl. CPC H10F 77/492

(57) ABSTRACT

The disclosure is directed to a solar module comprising at least one photovoltaic cell arranged in an essentially planar photovoltaic layer. The photovoltaic layer is being arranged between a front face and a back face of the solar module and a camouflaging for angle dependent reduction of the visibility of the at least one photovoltaic cell for a predefined range of viewing angles with respect to the front face.

### FIELD OF THE DISCLOSURE

The present disclosure relates to a solar module, in particular to solar modules having a reduced visibility of their photovoltaic cells, and a method for manufacturing the same.

### BACKGROUND OF THE DISCLOSURE

Solar modules in general are known from the prior art and typically comprise a layer of photovoltaic cells arranged between a front and a back sheet. The front sheet usually consists of a uniform optically translucent material in order to allow sunlight to reach the photovoltaic cells. This usually results in highly efficient solar modules, however from an architectural or design perspective, c of the photovoltaic cells fully visible through the translucent front sheet is often regarded as disruptive. This visual appearance of the solar modules often limits their placement to building surfaces, where they are not visible from the outside, such as flat roofs. Therefore, solar modules should be constructed to improve their visual appearance, while keeping a high efficiency possible.

Some attempts are known from the prior art, discussed briefly hereinafter.

US2018130921AA published in May 2018 in the name of Tesla and Solarcity relates to a Building integrated photovoltaic (BIPV) system, comprising solar panel arrays that can be aesthetically pleasing and appear seamless to an observer. Micro louvered structures are incorporated into photovoltaic (PV) stacks, such that light entering a PV stack that is reflected off of embedded solar cells is not directed out at angles at which a typical observer would normally view the PV stack or roof on which a solar array is installed.

US2018269824AA published in September 2018 in the name of Tesla relates to a solar tile having an obscured photovoltaic layer. The solar tile includes a back-sheet layer. The solar tile includes a bottom encapsulant layer adjacent to the back-sheet layer. The solar tile includes a louver layer having porous louvers. A top encapsulant layer is provided adjacent to the one or more photovoltaic cells. The top encapsulant layer has a plurality of louvers constructed therein to block side view of the one or more photovoltaic cells. The solar tile further includes a top layer adjacent to the top encapsulant layer.

### SUMMARY OF THE DISCLOSURE

For angled roofs and in particular facades, visually appealing solar modules are favorable to increase their acceptance by building owners and architects alike. Thus a solar module camouflaging its photovoltaic cells, while allowing for a high efficiency and simple manufacturing is disclosed.

A first aspect of the disclosure is directed to a solar module comprising at least one photovoltaic cell arranged in an essentially planar photovoltaic layer. The photovoltaic layer is being arranged between a front face and a back face of the solar module. A camouflaging is being arranged in front of the at least one photovoltaic cell for angle dependent reduction of the visibility of the at least one photovoltaic cell for a predefined range of viewing angles with respect to the front face. This allows to install the solar module at a building, such that the photovoltaic cells are less or not visible for an observer outside of the building on ground level, while sunlight can still be efficiently absorbed due to its incidence angle.

In general, the camouflaging in front of the at least one photovoltaic cell comprises a first pattern of camouflaging elements and a second pattern of camouflaging elements. The first pattern of camouflaging elements being arranged in a first layer in front the photovoltaic layer and being spaced apart therefrom by a first substrate layer of essentially translucent material. The second pattern of camouflaging elements being arranged in a second layer in front of the first layer and being spaced apart therefrom by a second substrate layer of essentially translucent material. In order to achieve an angle dependent reduction of the visibility of the at least one photovoltaic cell, the first pattern of camouflaging elements is being arranged shifted relative to the second pattern of camouflaging elements by a certain offset in a first direction parallel to the general extension of the first and the second layer.

More than two patterns of camouflaging elements being arranged in two spaced apart layers are possible, however there are typically less than five, like three and four pattern of camouflaging elements arranged on top of each other and respectively with an offset in the first direction with respect to the neighboring patterns of camouflaging elements.

Good results are possible when the camouflaging elements have a lower optical transmissibility than the first and/or second substrate layer. The camouflaging elements can have a transmission coefficient between 0 and 0.9, preferably between 0.1 and 0.5. The lower transmissibility of the camouflaging elements can be achieved by absorption and/or scattering. Depending on the application the optical transmissibility can be uniform for the camouflaging elements of the respective first or second pattern, however, the optical transmissibility of the camouflaging elements may vary within the first and/or the second pattern or within individual camouflaging elements. Camouflaging elements can be separated (e.g. parallel stripes or dots unconnected to each other) within the respective first or second layer, however a continuous pattern (e.g. a honey-comb pattern) is possible as well, wherein camouflaging elements can be viewed as (periodically) reoccurring elements of the continuous pattern.

Preferably the camouflaging elements are essentially two dimensional. Two dimensional can be understood as having a general extension parallel to the photovoltaic layer that is multiple times the extension of the camouflaging elements in a direction perpendicular to the photovoltaic layer. This allows a simpler manufacturing of the solar modules compared to those of the prior art having three dimensional obscuring means, since amongst others conventional lamination processes can be applied.

In preferred variations the first and/or the second pattern of camouflaging elements is formed as a dot pattern, a stripe pattern, a pattern of polygonal elements, a honey-comb pattern or a combination thereof. However, depending on the design, other patterns are possible, such as randomized patch pattern. Preferably the stripes of the stripe pattern extend in second direction parallel to the general extension of the first or the second layer respectively and, in particular with their general extension perpendicular to the first direction. The camouflaging elements may span essentially across the solar module (in the second direction).

The offset in combination with a width of a camouflaging element in the first direction typically defines the range of viewing angles maximizing the reduction of the visibility of the at least one photovoltaic cell. Under these viewing angles a parallel projection of the offset camouflaging elements covers a maximum of the at least one photovoltaic cell, such that its visibility is minimized. The viewing angles are defined in particular in combination with a distance between the first and the second layer in a third direction perpendicular to the first and the second direction. The width of the camouflaging elements in the first direction and the offset between the first and the second pattern is preferably selected to maximize the reduction of visibility for viewing angles between 90 and 45 degrees relative to the first direction, in particular between 85 and 50 degrees.

The offset O and the distance D between the first and the second layer in relation to the width W of the camouflaging elements of the respective pattern can be expressed as an inequality for the viewing angles α (for which the visibility is reduced):

$$α \geq arctan ( \frac{W - O}{D} )$$

In case of a lower limit for the viewing angles of e.g. 45 degrees for which the visibility is reduced, the relation between the offset, the distance and the width is W−O≈D. The Difference of the width and the offset can be understood as an overlap of a camouflaging element of the first layer and the second layer as seen in the third direction.

To achieve good performance, the camouflaging comprises at least one film of essentially translucent material and/or at least one sheet of glass, carrying camouflaging elements. Preferably the camouflaging comprises the at least one film and/or at least one sheet of glass having applied onto two opposite faces camouflaging elements. Alternatively, or in addition, the camouflaging can comprise at least two films of essentially translucent material or at least two sheets of glass each having applied onto at least one face camouflaging elements, the at least two films being arranged in a cross-sectional view on top of each other. The two films or sheets of glass can have an identical pattern of camouflaging elements applied thereon and the offset therebetween is achieved by aligning the two films and/or sheets of glass during manufacturing of the solar module.

The film or sheet of glass forming the top face of the solar module can be designed individually. In particular, structured glass types can be used, as these can receive camouflaging elements onto their surface similarly as smooth glass. By positioning the camouflaging elements according to the glass and its structure, the effect is achieved that the light hits the solar cells without being substantially obstructed by the camouflaging elements, but to the eye of the observer it still appears to be a for example colored facade element.

Depending on the application, the camouflaging elements are applied to a face of at least one film or sheet of glass by printing, edging, lamination, sandblasting and/or gluing. Preferably the camouflaging elements consist at least partially of color pigments, a textile, metal or a combination thereof. This allows a wide variety of visual appearances and therefore applications of solar modules according to the disclosure.

Alternatively or in addition, camouflaging elements consist at least partially of a partially reflective coating configured to reflect incoming light depending on the wave-length and/or the incidence angle thereof. This allows, depending on the viewing angle, a color impression of the solar module to be achieved. The partially reflective coating can, for example, reflect light of a predefinable wave-length or wave-length range and transmit other wavelengths due to interferential effects. This allows to increase the amount of light available at the photovoltaic cell, while the reduction of the visibility of the at least one photovoltaic cell is maintained for certain viewing angles. Depending on the field of application the coating comprises one or more layer, in particular alternating layers of different refractive indices, preferably forming a Bragg filter.

In preferred variations, the first and the second pattern of camouflaging elements have at least in regions an essentially equal spatial period, in particular in the first and/or the second direction. The spatial period can be understood as the distance between individual camouflaging elements. In other words, the first and the second pattern of camouflaging elements form at least in regions a regular pattern.

In some variations a coating is arranged on a first face of a film of essentially translucent material or sheet of glass, said film or sheet of glass acting as a combination of the first layer and the first substrate layer or as the combination of the second layer and the second substrate layer. The coating is preferably a partially reflective coating configured to reflect incoming light depending on the wave-length and/or the incidence angle thereof. The coating can this way create a color impression of the solar module, in particular for certain viewing angles. Examples for possible coatings are so called thin film coatings acting as light filters. Depending on the design, the coating is arranged between the front face and the camouflaging.

A second aspect of the disclosure is directed to a method for manufacturing solar modules as described above. The method typically comprises the steps of providing a stack of layers stacked in a vertical direction and lamination of the stack to form a solar module.

The stack usually comprises a photovoltaic layer comprising at least one photovoltaic cell and a first substrate layer of essentially translucent material being arranged on top of the photovoltaic layer and a first layer with a first pattern of camouflaging elements being arranged on top of the first substrate layer. A second substrate layer of essentially translucent material being arranged on top of the first layer and second layer with a second pattern of camouflaging elements being arranged on top of the second substrate layer and being arranged shifted relative to the first pattern of camouflaging elements by a certain offset in a first direction parallel to the general extension of the first and the second layer.

Alternatively, the layers of the stack can be arranged in reverse order, depending on the circumstances.

In a preferred variation the method comprises the step of printing at least one pattern of camouflaging elements onto a first face of a film of essentially translucent material or sheet of glass, said film or sheet of glass acting as a combination of the first layer and the first substrate layer or as the combination of the second layer and the second substrate layer. Alternatively, or in addition, the method comprises the step of printing a first pattern of camouflaging elements onto a first face of a film or sheet of glass and a second pattern of camouflaging elements onto a second face of the film or sheet of glass, said film or sheet of glass acting as a combination of the first layer, the second layer and the second substrate layer therebetween.

Alternatively or in addition, the method may use a gas deposition process to apply at least one of the first and the second pattern of camouflaging elements. The gas deposition process is preferably one of the following: Chemical Vapor Deposition (CVD) or Physical Vapor Deposition (PVD). Preferably a mask is temporarily applied to the first face of the film or of the sheet of glass, such that the first and/or the second pattern of camouflaging elements is formed during an essentially uniform dispositioning of material of the camouflaging elements. The use of a gas deposition process allows to increase the precision with which the pattern(s) are applied and thus the quality of the pattern(s). As a result, e.g. the spatial period can be reduced. Depending on the field of application two or more layers of material are applied to form the coating, in particular alternating layers of different refractive indices. The layers forming the coating are preferably thin layers with a thickness between 1 nm and 500 nm (nano meters), in particular between 100 nm and 200 nm.

In a preferred variation the method comprises the step of applying at least one pattern of camouflaging elements by a gas deposition process onto a first face of a film of essentially translucent material or sheet of glass, said film or sheet of glass acting as a combination of the first layer and the first substrate layer or as the combination of the second layer and the second substrate layer. Alternatively, or in addition, the method comprises the step of applying a first pattern of camouflaging elements by a gas deposition process onto a first face of a film or sheet of glass and a second pattern of camouflaging elements onto a second face of the film or sheet of glass, said film or sheet of glass acting as a combination of the first layer, the second layer and the second substrate layer therebetween.

In some variations the method comprises the step of applying a coating, in particular a thin film coating, onto a first face of a film of essentially translucent material or sheet of glass, said film or sheet of glass acting as a combination of the first layer and the first substrate layer or as the combination of the second layer and the second substrate layer. Preferably the coating is applied using a CVD or a PVD process.

A third aspect of the disclosure is directed to a kit of parts comprising at least one solar module as described above and mounting elements for mounting said solar module to a surface of a building, in particular a wall of a building.

It is to be understood that both the foregoing general description and the following detailed description present embodiments, and are intended to provide an overview or framework for understanding the nature and character of the disclosure. The accompanying drawings are included to provide a further understanding, and are incorporated into and constitute a part of this specification. The drawings illustrate various embodiments, and together with the description serve to explain the principles and operation of the concepts disclosed.

### BRIEF DESCRIPTION OF THE DRAWINGS

The herein described disclosure will be more fully understood from the detailed description given herein below and the accompanying drawings which should not be considered limiting to the disclosure described in the appended claims. The drawings are showing:

FIG. 1 a cross-sectional view of a first variation of a solar module according to the disclosure;

FIG. 2 the first variation of FIG. 1 with the viewing angle of an observer;

FIG. 3 the first variation of FIG. 1 with the incidence angle of the sunlight;

FIG. 4 a cross-sectional view of a second variation of a solar module according to the disclosure; and

FIG. 5 a cross-sectional view of a third variation of a solar module according to the disclosure;

### DESCRIPTION OF THE EMBODIMENTS

Reference will now be made in detail to certain embodiments, examples of which are illustrated in the accompanying drawings, in which some, but not all features are shown. Indeed, embodiments disclosed herein may be embodied in many different forms and should not be construed as limited to the embodiments set forth herein; rather, these embodiments are provided so that this disclosure will satisfy applicable legal requirements. Whenever possible, like reference numbers will be used to refer to like components or parts.

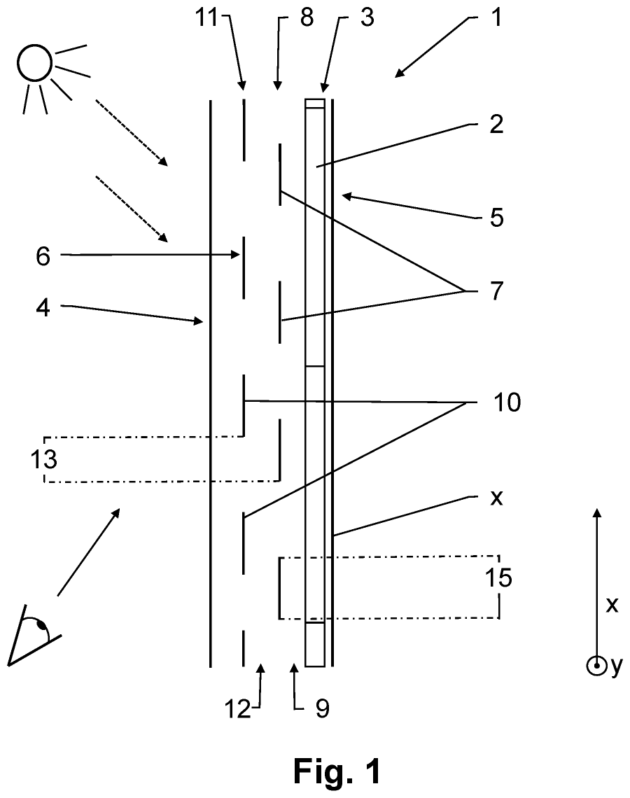

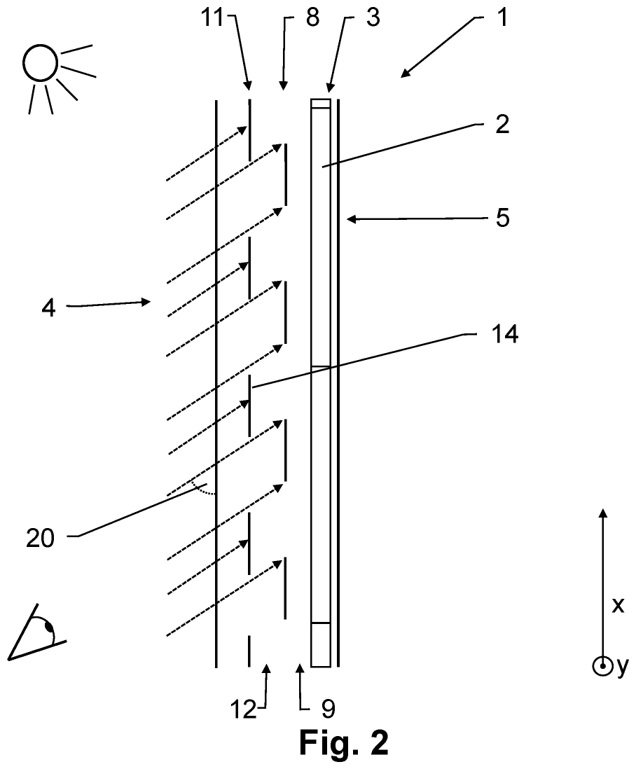

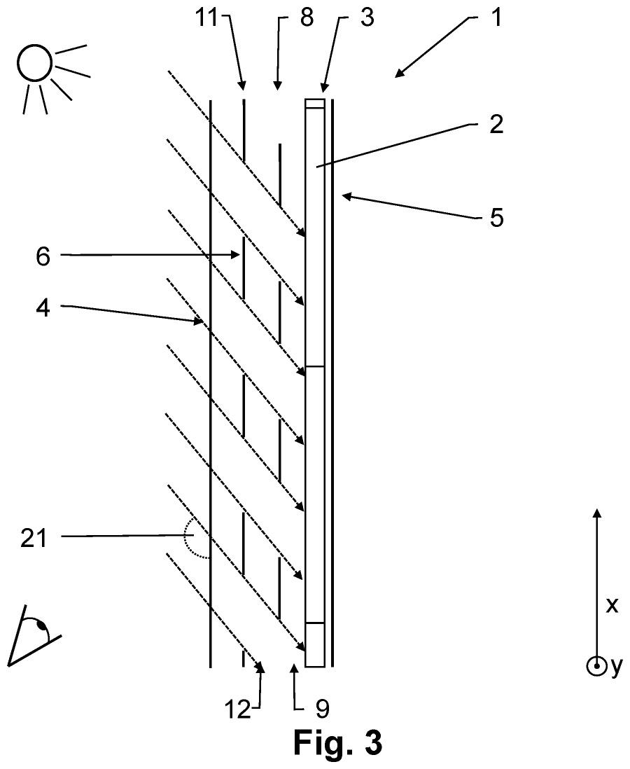

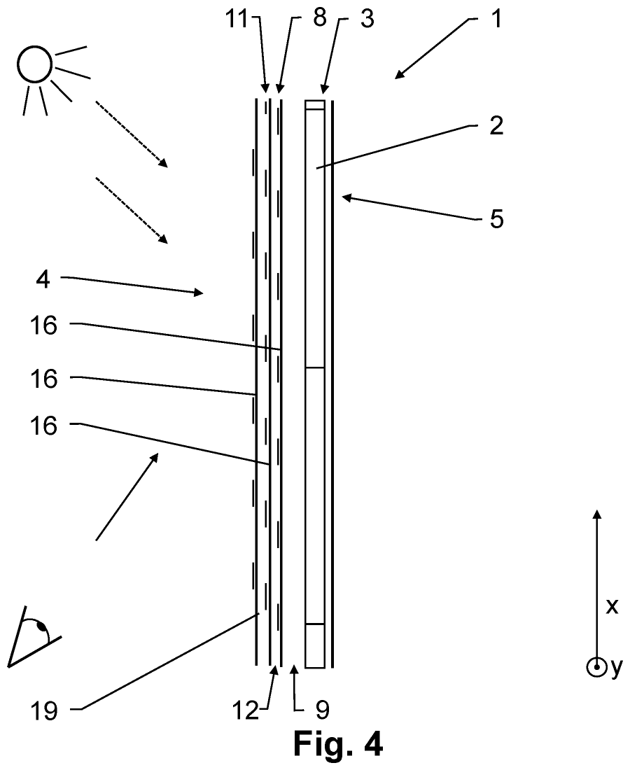

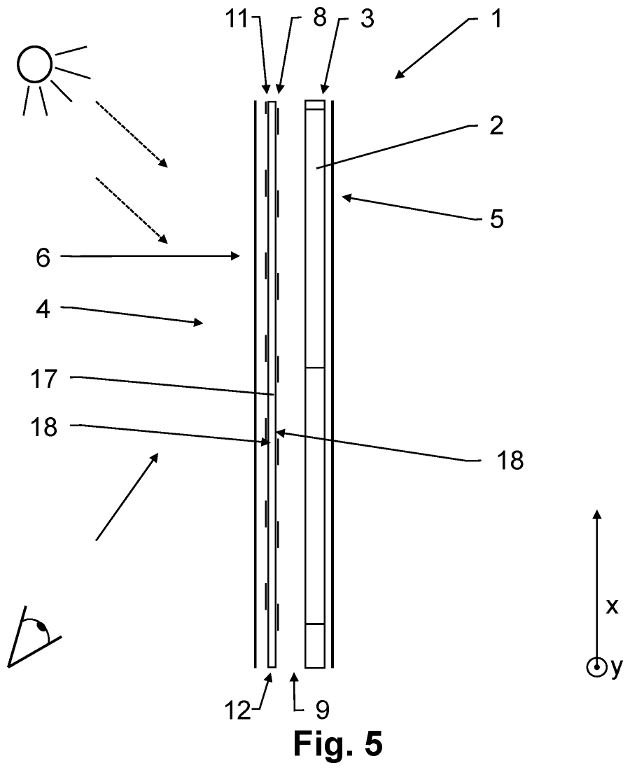

FIG. 1 shows a cross-sectional view of a first variation of a solar module 1 according to the disclosure. FIG. 2 shows the first variation of FIG. 1 with the viewing angle of an observer and FIG. 3 shows the first variation of FIG. 1 with the incidence angle of the sunlight. FIG. 4 shows a cross-sectional view of a second variation of a solar module 1 according to the disclosure and FIG. 5 shows a cross-sectional view of a third variation of a solar module 1 according to the disclosure.

Solar modules 1 according to the disclosure, as shown in FIG. 1, typically comprise an essentially planar photovoltaic layer 3 having at least one photovoltaic cell 2. The photovoltaic layer 3 is arranged between a front face 4 and a back face 5. The back face 5 is typically provided by a back sheet of protective material. The front face 4 can be provided by a film 16 or a sheet of glass 17 or a layer of encapsulant material, or a combination thereof. Between the front face 4 and the photovoltaic layer 3 a camouflaging 6 is arranged for an angle dependent reduction of the visibility of the at least one photovoltaic cell 2 for a predefined range of viewing angles 20 with respect to the front face 4, see FIG. 2. The camouflaging 6 may form part of the front face 4.

To achieve an angle dependent reduction of the visibility, the camouflaging 6 comprises a first pattern of camouflaging elements 7 arranged in a first layer 8 in front of the photovoltaic layer 3 and a second pattern of camouflaging elements 10 arranged in a second layer 11 in front of the first layer 8. Between the first layer 8 and the photovoltaic layer 3 a first substrate layer 9 of essentially translucent material is arranged. Between the second and the first layer 11, 8 a second substrate layer 12 of essentially translucent material is arranged. The substrate layers 9, 12 space apart the first layer 8 from the photovoltaic layer 3 and the second layer 11 from the first layer 8. The first pattern of camouflaging elements 7 is preferably shifted relative to the second pattern of camouflaging elements 10 by an offset 13 in a first direction x parallel to the photovoltaic layer 3.

Preferably the camouflaging elements 14 are essentially two dimensional. They are indicated in FIGS. 1 to 5 by lines parallel to the photovoltaic layer 3 and typically have a lower optical transmissibility compared to the substrate layers 9, 12. Depending on the desired appearance and optical transmissibility, the camouflaging elements 14 can consist at least partially of color pigments, a textile, metal or a combination thereof. In the shown variations, the camouflaging elements 14 are made from paint, usually printed onto a substrate layer 9, 12.

The first and the third variation, as shown in FIGS. 1 to 3 and 5, comprise two patterns of camouflaging elements 14. The second variation, as shown in FIG. 4 comprises an additional third patterns of camouflaging elements 14 compared to the first and the third variation. The width 15 of the individual camouflaging elements 14 can be reduced in the second variation compared to the first and the third variation. This is since the offset 13 between the patterns of camouflaging elements 14 in combination with the width 15 of a camouflaging element in the first direction x defines the range of viewing angles 20 maximizing the reduction of the visibility of the at least one photovoltaic cell 2. The patterns in the shown variations is a stipe pattern, however other patterns are possible.

In the third variation shown in FIG. 5, the camouflaging comprises a sheet of glass 17 carrying camouflaging elements 14. A first pattern of camouflaging elements 7 is applied to a face 18 of the sheet of glass 17 facing the photovoltaic layer 3 and a second pattern of camouflaging elements 10 is applied to an opposite face 18 of the sheet of glass 17 facing the front face 4. A face 18 of the sheet of glass 17 opposite from the photovoltaic layer 3 can form part of the front face 4 of the solar module 1. This face 18 can be smooth or structured glass.

In the second variation, as shown in FIG. 4, the camouflaging comprises three films 16 having respectively applied camouflaging elements 14 onto one face 18 of the respective film 16 and being arranged shifted relative to each other in the first direction x by the offset 13 respectively. The films 16 can at least partially consist of Ethylene Vinyl Acetate (EVA) or Polyvinyl Butyral (PVB).

Rather, the words used in the specification are words of description rather than limitation, and it is understood that various changes may be made without departing from the scope of the disclosure.

### LIST OF DESIGNATIONS

1 Solar module
2 Photovoltaic cell
3 Photovoltaic layer
4 Front face
5 Back face
6 Camouflaging
7 First pattern of camouflaging elements
8 First layer
9 First substrate layer
10 Second pattern of camouflaging elements
11 Second layer
12 Second substrate layer
13 Offset
14 Camouflaging element
15 Width (camouflaging element)
16 Film
17 Sheet of glass
18 Face (of film or sheet of glass)
19 Stack of layers
20 Viewing angle (observer)
21 Incidence angle (sunlight)

1. A solar module comprising
a. at least one photovoltaic cell arranged in an essentially planar photovoltaic layer, the photovoltaic layer being arranged between a front face and a back face of the solar module; and
b. a camouflaging for angle dependent reduction of the visibility of the at least one photovoltaic cell for a predefined range of viewing angles with respect to the front face, the camouflaging being arranged in front of the at least one photovoltaic cell and comprising
i. a first pattern of camouflaging elements being arranged in a first layer in front the photovoltaic layer and being spaced apart therefrom by a first substrate layer of essentially translucent material; and
ii. a second pattern of camouflaging elements being arranged in a second layer in front of the first layer and being spaced apart therefrom by a second substrate layer of essentially translucent material; wherein
iii. the first pattern of camouflaging elements being arranged shifted relative to the second pattern of camouflaging elements by a certain offset in a first direction (x) parallel to the general extension of the first and the second layer, such that depending on the viewing angle the visibility of the at least one photovoltaic cell is reduced.

2. The solar module according to claim 1, wherein the camouflaging elements have a lower optical transmissibility than the first and/or second substrate layer.

3. The solar module according to claim 1, wherein the camouflaging elements are essentially two dimensional.

4. The solar module according to claim 1, wherein the first and/or the second pattern of camouflaging elements is formed as a dot pattern, a stripe pattern, a pattern of polygonal elements, a honey-comb pattern or a combination thereof.

5. The solar module according to claim 4, wherein the stripes of the stripe pattern extend in a second direction (y) parallel to the general extension of the first or the second layer respectively and, in particular essentially perpendicular to the first direction (x).

6. The solar module according to claim 1, wherein the offset in combination with a width of a camouflaging element in the first direction (x), in particular in combination with a distance between the first and the second layer in a third direction perpendicular to the first and the second direction, defines the range of viewing angles maximizing the reduction of the visibility of the at least one photovoltaic cell.

7. The solar module according to claim 1, wherein the camouflaging comprises at least one film of essentially translucent material and/or at least one sheet of glass, carrying camouflaging elements.

8. The solar module according to claim 7, wherein the camouflaging comprises
a. the at least one film and/or at least one sheet of glass having applied onto two opposite faces camouflaging elements; and/or
b. at least two films of essentially translucent material or at least two sheets of glass each having applied onto at least one face camouflaging elements, the at least two films being arranged in a cross-sectional view on top of each other.

9. The solar module according to claim 1, wherein the camouflaging elements are applied to a face of at least one film or sheet of glass by printing, edging, sandblasting, lamination and gluing.

10. The solar module according to claim 1, wherein the camouflaging elements consist at least partially of color pigments, a textile, metal or a combination thereof.

11. The solar module according to claim 1, wherein the first and the second pattern of camouflaging elements have at least in regions an essentially equal spatial period, in particular in the first and/or the second direction (x, y).

12. The solar module according to claim 5, wherein the camouflaging elements span essentially across the solar module.

13. The solar module according to claim 1, wherein the camouflaging elements consist at least partially of a partially reflective coating configured to reflect incoming light depending on the wave-length and/or the incidence angle.

14. A method for manufacturing solar modules according to claim 1, the method comprising the steps of
a. providing a stack of layers stacked in a vertical direction (z), the stack comprising:
i. a photovoltaic layer comprising at least one photovoltaic cell; and
ii. a first substrate layer of essentially translucent material arranged on top of the photovoltaic layer; and
iii. a first layer with a first pattern of camouflaging elements arranged on top of the first substrate layer; and
iv. a second substrate layer of essentially translucent material arranged on top of the first layer; and
v. second layer with a second pattern of camouflaging elements arranged on top of the second substrate layer and being arranged shifted relative to the first pattern of camouflaging elements by a certain offset in a first direction (x) parallel to the general extension of the first and the second layer; and
b. lamination of the stack to form a solar module.

15. The method according to claim 14, wherein the method comprises the steps of:
a. printing at least one pattern of camouflaging elements onto a first face of a film of essentially translucent material or sheet of glass, said film or sheet of glass acting as a combination of the first layer and the first substrate layer or as the combination of the second layer and the second substrate layer, and/or
b. printing a first pattern of camouflaging elements onto a first face of a film or sheet of glass and a second pattern of camouflaging elements onto a second face of the film or sheet of glass, said film or sheet of glass acting as a combination of the first layer, the second layer and the second substrate layer therebetween.

16. The method according to claim 14, wherein the method comprises the steps of:
a. applying at least one pattern of camouflaging elements by a gas deposition process onto a first face of a film of essentially translucent material or sheet of glass, said film or sheet of glass acting as a combination of the first layer and the first substrate layer or as the combination of the second layer and the second substrate layer, and/or
b. applying a first pattern of camouflaging elements by a gas deposition process onto a first face of a film or sheet of glass and a second pattern of camouflaging elements onto a second face of the film or sheet of glass, said film or sheet of glass acting as a combination of the first layer, the second layer and the second substrate layer therebetween.

17. A kit of parts comprising at least one solar module according claim 1 and mounting elements for mounting said solar module to a wall of a building.
